(19) United States
(12) Patent Application Publication
(10) Pub. No.: US 2016/0169949 A1
(43) Pub. Date: Jun. 16, 2016

(54) SYSTEMS AND METHODS FOR UTILITY MONITORING

(71) Applicant: Citilogics, LLC, Cincinnati, OH (US)

(72) Inventors: Sam P. Hatchett, Norwood, OH (US); Stuart M. Hooper, Cincinnati, OH (US); James G. Uber, Cincinnati, OH (US)

(73) Assignee: CITILOGICS, LLC, Cincinnati, OH (US)

(21) Appl. No.: 14/568,795

(22) Filed: Dec. 12, 2014

(51) Int. Cl. G01R 21/133; G06F 3/0484

(52) U.S. Cl. CPC G01R 21/133; G06F 3/04847; G06F 3/04842

(57) ABSTRACT

Embodiments described herein include systems and methods for utility monitoring. Accordingly, some embodiments include receiving utility data from a utility, where the utility data includes operational data of the utility for a predetermined area of the utility, determining a subset of the utility that identifies a district metered area (DMA), and determining a first flow rate into a subset of the utility. Some embodiments include determining a second flow rate out of a subset of the utility, detecting a change in the utility based on the first flow rate and/or the second flow rate, altering the subset of the utility, based on the change, and providing data related to the subset to a user.

### BACKGROUND

1. Field

Embodiments provided herein generally relate to systems and methods for utility monitoring, and particularly to determining areas of a utility system to monitor, as well as providing a customizable interface for monitoring that utility system.

2. Technical Background

Many utilities such as water companies, electric companies and the like often attempt to monitor usage of the utility they provide. As an example, a water company may desire to monitor usage for one or more areas that the water company serves. Accordingly, many utilities may currently create a model to represent the utility area, but are generally unable to provide real time, customized modeling and prediction of the monitored areas.

### SUMMARY

Embodiments described herein include systems and methods for utility monitoring. Accordingly, some embodiments include receiving utility data from a utility, where the utility data includes operational data of the utility for a predetermined area of the utility, determining a subset of the utility that identifies a district metered area (DMA), and determining a first flow rate into a subset of the utility. Some embodiments include determining a second flow rate out of a subset of the utility, detecting a change in the utility based on the first flow rate and/or the second flow rate, altering the subset of the utility, based on the change, and providing data related to the subset to a user.

In another embodiment, a method may include receiving utility data from a utility, where the utility data includes operational data of the utility for a predetermined area of the utility, providing a user interface that presents the utility data to a user, and providing a user option to create a hypothetical usage scenario for the utility. In some embodiments, the method includes predicting an issue based on the hypothetical usage scenario, determining a solution to the issue, and providing the solution to the user for implementation.

In yet another embodiment, a non-transitory computer-readable medium may cause a computing device to receive utility data from a utility, where the utility data includes operational data of the utility for a predetermined area of the utility, determine a subset of the utility that identifies a district metered area (DMA) based on the operational data, and detect a change in the utility. In some embodiment the non-transitory computer-readable medium may cause the computing device to automatically alter the subset, based on the change and provide data related to the subset to a user.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 depicts a computing environment for utility monitoring, according to one or more embodiments disclosed herein;

FIG. 2 depicts a user interface that may be provided for monitoring one or more utilities, according to embodiments disclosed herein;

FIG. 3 depicts a map section of the user interface from FIG. 2, according to embodiments disclosed herein;

FIG. 4A depicts a time series section of the user interface from FIG. 2, according to embodiments disclosed herein;

FIG. 4B depicts a clocks section of the user interface from FIG. 2, according to embodiments disclosed herein;

FIG. 4C depicts a model section of the user interface from FIG. 2, according to embodiments disclosed herein;

FIG. 4D depicts a district metered area (DMA) section of the user interface from FIG. 2, according to embodiments disclosed herein;

FIG. 5 depicts a graphical area of the user interface from FIG. 2, according to embodiments disclosed herein;

FIGS. 6A-6D depict a canvas area of the user interface from FIG. 2, according to embodiments disclosed herein;

FIGS. 7A-7B depict a change in a utility system, as provided in the map section of the user interface of FIG. 2, according to embodiments disclosed herein;

FIG. 8 depicts a flowchart for providing monitoring of one or more utilities, according to embodiments disclosed herein; and

FIG. 9 depicts a remote computing device for utility monitoring, according to one or more embodiments disclosed herein.

### DETAILED DESCRIPTION

Embodiments described herein are configured with hardware and/or software for monitoring one or more utilities. As an example, embodiments described herein may be built on a real-time modeling platform, such as EPANET-RTX (developed by the EPA) and thus may configured to capture real time data (such as operational data that indicates usage and/or other information) from a remote database related to parameters of a water company system. The real time data may be received within a time period that is updated based on availability of new data (such as on the scale of about a microsecond to a scale of about hours). The data may then be utilized for simulating predicted future events, monitoring current events, as well as comparing the predicted events with the actual events. This allows operators to determine the predicted effects of control decisions, such as responding to system failures and operator training.

Additionally described herein is a graphical user interface that includes a mapping of the parameters in real time and identification of a plurality of points and at least one district metered area (DMA) associated with the measured parameters. Real time graphical representations may additionally be provided to identify current usages, pipeline points of failure, and/or other data associated with the utility.

Embodiments described herein may also be configured such that the software is highly adaptable as an off-the-shelf component that may be easily implemented and configured in any number of different systems. Accordingly, administrator interfaces may be provided for easily configuring the software into a new utility system.

Embodiments may also be configured to monitor actual usage of the utility. This information may be compared with predicted usage in order to assess accuracy of the predictions. Based on the accuracy of the prediction, an algorithm utilized to predict the usage may be altered. Additionally, inaccuracies in the system may indicate that a portion of the utility has a leak or break. As an example, if a prediction is made and the results appear different based on historical data, a determination may be made that there is an issue to account for this discrepancy. Thus, the issue may be alerted to the user for reviewing and/or addressing.

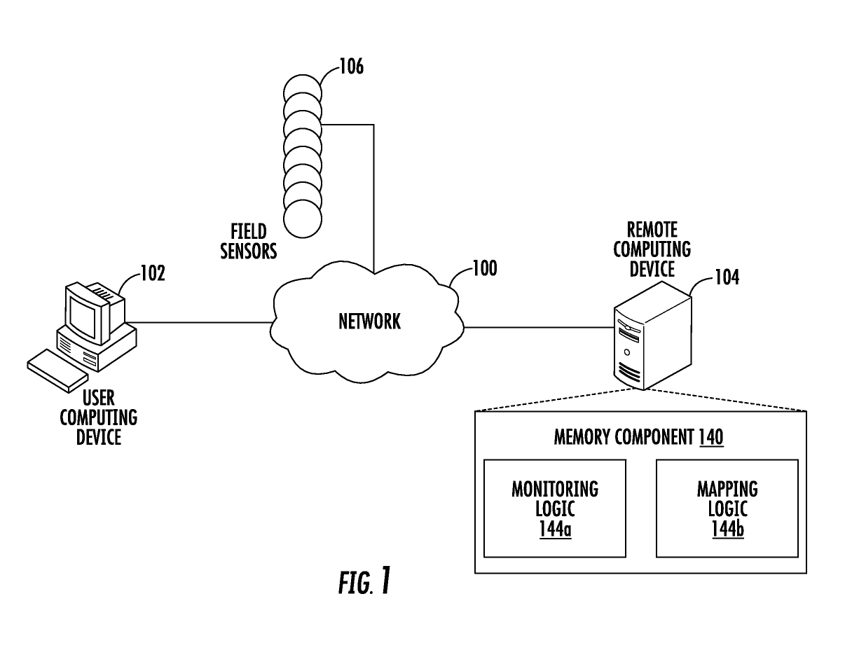

Referring now to the drawings, FIG. 1 depicts a computing environment for utility monitoring, according to one or more embodiments disclosed herein. As illustrated, a network 100 may be coupled to a user computing device 102, a remote computing device 104, and a plurality of field sensors 106. The network 100 may include a wide area network, such as the internet, a cellular network (such as 3G, 4G, 4G LTE, WiMax, etc.). Similarly, the network 100 may include a local area network, such as a wireless fidelity (WiFi) network, a Bluetooth network, a near field communication network, hardwire, etc.

The user computing device 102 may be coupled to the network 100 and may be configured as a personal computer, laptop computer, mobile device, tablet, and/or other computing device that may be operated by personnel of a utility. Similarly, the remote computing device 104 may be configured as a server, a tablet, a personal computer, and/or other device for performing the functionality described herein. The remote computing device 104 may be operated by an administrator and/or other provider of the functionality for the utility.

The field sensors 106 may include a flow sensor on a pipe, a fill sensor on a tank, power sensors on equipment, and/or similar sensors for a water utility. Similar, the field sensors 106 may include voltage meters, amperage meters, resistance meters, impedance meters, capacitance meters, and/or other sensors for an electrical utility. Other utilities may implement similar sensors, which would be included within the scope of this discussion.

As an example, some embodiments of the field sensors 106 may include a programmable logic control (PLC) device. The PLC device may be utilized for receiving the data from the field sensor and communicating a formatted signal to the remote computing device 104. Depending on the particular embodiment, a different PLC may be associated with each field sensor 106, while other embodiments may utilize a common PLC for a plurality of field sensors 106.

The remote computing device 104 may include a memory component 140 that may store logic, such as monitoring logic 144a and mapping logic 144b. The monitoring logic 144a may be executed by a processor (such as processor 930 from FIG. 9) of the remote computing device 104 to cause the remote computing device 104 to receive one or more signals (such as a first signal and a second signal) from the field sensors 106 within the utility and determine the status of one or more portions of the utility. The mapping logic 144b may cause the remote computing device 104 to utilize the detected signals and determine associated data, such as maps, DMAs, graphs, and/or other features described below. Other components of the remote computing device 104 may be provided in FIG. 9, described in more detail, below.

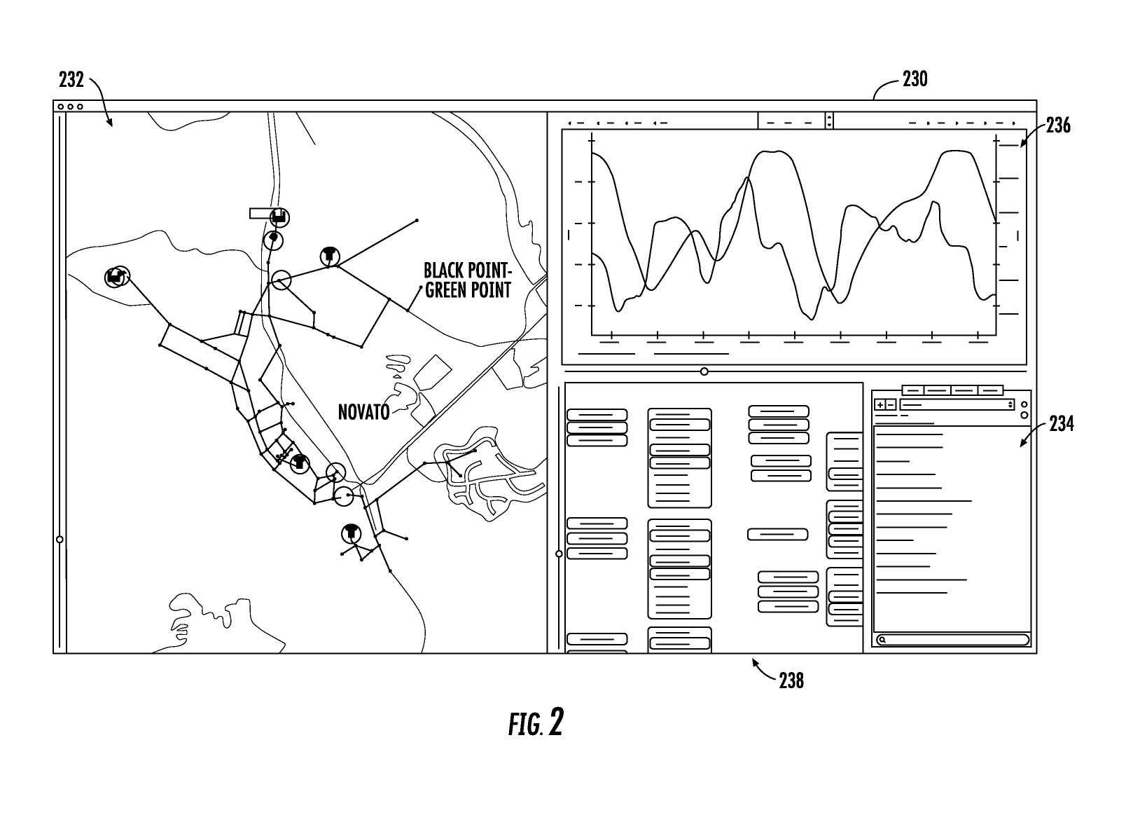

FIG. 2 depicts a user interface 230 that may be provided for monitoring one or more utilities, according to embodiments disclosed herein. As illustrated, the user interface 230 includes a map section 232, a utility information section 234, a graphical section 236, and a canvas section 238. Specifically, the map section 232 may be configured to provide a pictorial representation of a utility. The remote computing device 104 may receive information related to the location of various utility components, such as pipes, pumps, etc. and may determine a pictorial representation of this system. In some embodiments, this pictorial representation may overlay a satellite (or other) image of the area. The map section 232 may additionally provide alerts related to determined issues with the system. As an example, if a malfunction with one of the components is determined, visual alerts may be provided indicating this issue. These alerts and/or other portions of the pictorial representation may be color coded, depending on the embodiment.

Additionally, the utility information section 234 may be configured to provide various types of predetermined data related to the utility system being depicted. As an example, the utility information section 234 may include options to view one or more of a plurality of DMAs, database information, clock information, and model information. The graphical section 236 may be configured to provide a graphical representation of one or more portions of the utility. As an example, the graphical representation may be related to flow data into and/or out of a predetermined DMA. In some embodiments, the graphical representation may be related to data associated with a predetermined module, as described below. Other data may be provided in the graphical section 236, depending on the embodiment and/or option selected.

The canvas section 238 may operate with the utility information section 234 to provide user options described herein. As an example, the user (which may be an administrator) may be provided with options to create at least one module that is represented as an icon related to the utility with one or more data streams. As an example, the module may be coupled with data from a selected database to monitor a portion of the utility, in response to a user selection of the option. These modules may be automatically updated and, in some embodiments may be shared with other users to provide a repository of modules to monitor different functions of the utility.

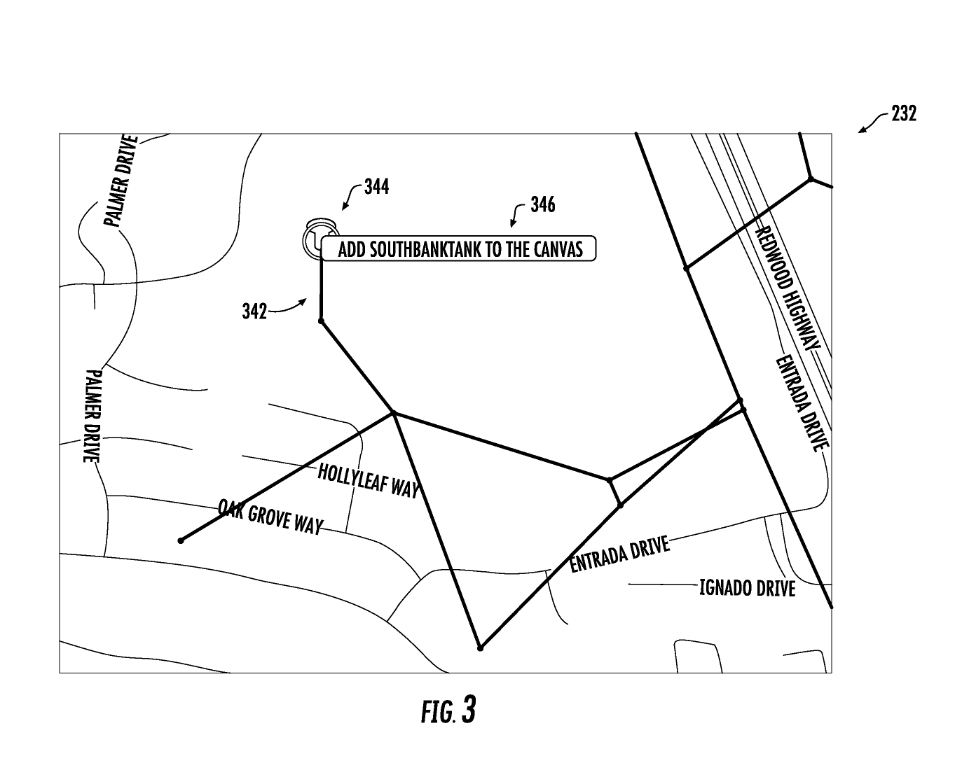

FIG. 3 depicts a map section 232 of the user interface 230 from FIG. 2, according to embodiments disclosed herein. As illustrated, a water utility is depicted with heavy lines representing water lines 342. A tank 344 is also depicted, as well as an option 346 for adding the tank to the canvas section 238 (FIG. 2). Specifically, the user may select a portion of the map section 232 for viewing data related to that section. As an example, if the user selects one of the water lines 342, flow data rates and/or other data may be determined and/or provided. If the user selects the tank 344, water volume, current operating state, and/or other information may be provided. Options for adding a portion of the utility to the canvas section 238 may also be provided. As described in more detail below, the canvas section 238 may be configured to crate modules to monitor a predetermined portion of the utility. Accordingly, if the user wishes include the “SouthbankTank” to the canvas, options for doing so may be provided in the map section 232.

It should be understood that some embodiments of this disclosure provide for real time updates of the utility, based on information received from one or more databases. As an example, if a field sensor 106 detects a change in the data being provided, the field sensor 106 may send that information to the remote computing device 104, which may update the data provided in the user interface 230 (FIG. 2), including the map section 232. This provides the ability to view various aspects of the utility in real-time.

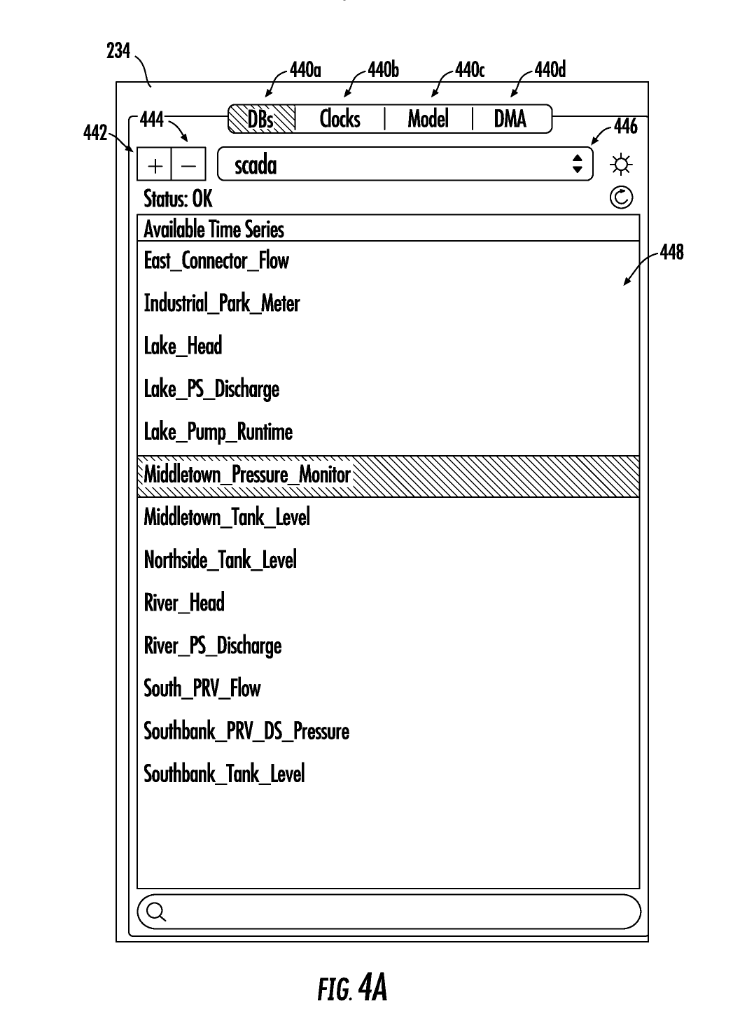

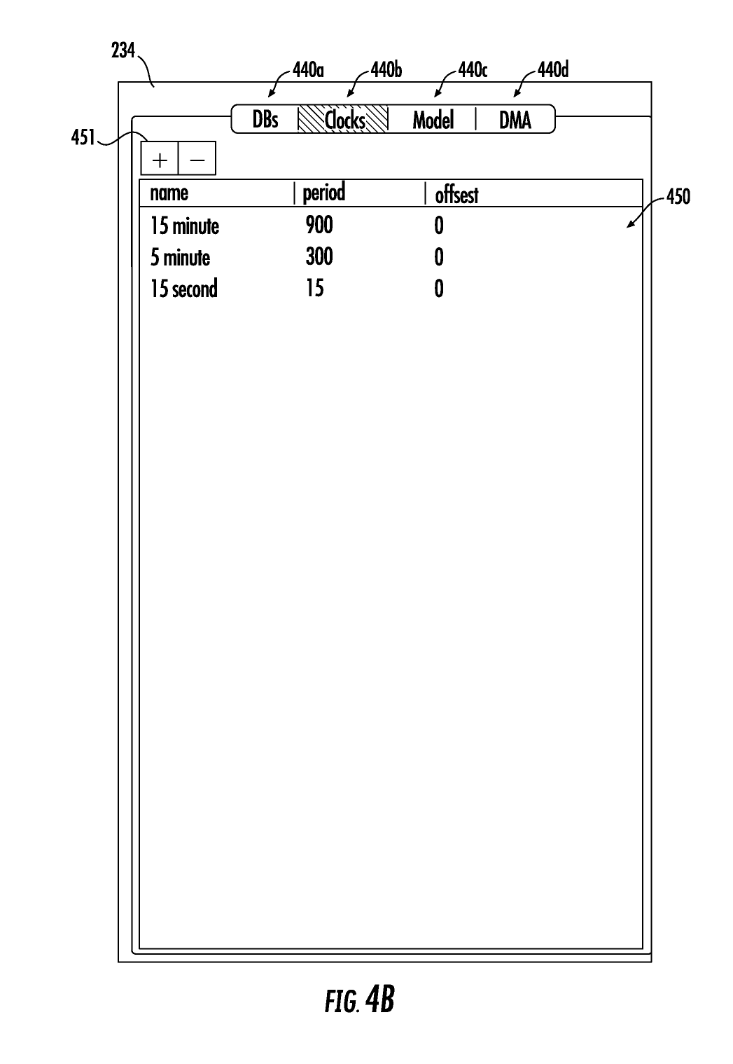

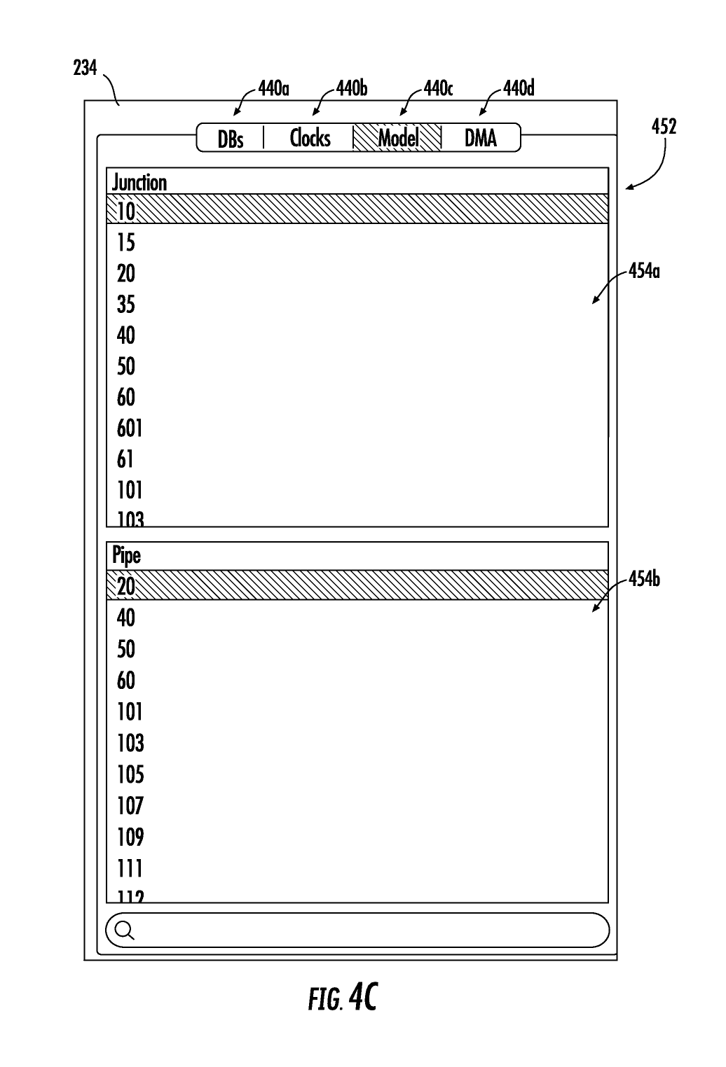

FIG. 4A depicts a time series section 448 of the user interface 230 from FIG. 2, according to embodiments disclosed herein. As illustrated, the utility information section 234 may include a plurality of options, such as a database option 440a, a clocks option 440b, a model option 440c, and a DMA option 440d. Also included are an add option 442, a subtract option 444, and a database field 446. An available time series section 448 is also provided. Specifically, by selecting the database option 440a, one or more databases may be provided. The databases may include information regarding the utility, such as SCADA data, and/or other data. Accordingly, the user may search and/or select a database from a list in the database field 446. The user may add or remove the database identified in the database field 446 via selection of the add option 442 and/or the subtract option 444.

In the available time series section 448 are one or more components and/or meter readings of the utility as provided by the selected database. In the example of FIG. 4, flow meters, water lines, lake discharge, pump run times, pressure monitors, tank levels, flow rates, pressures, and/or other components and data sources may be provided. Accordingly, the user may select one or more of these components and/or meter readings for inclusion into a module of the canvas section 238.

FIG. 4B depicts a clocks section 450 of the user interface 230 from FIG. 2, according to embodiments disclosed herein. As illustrated, the clocks section 450 includes a predetermined number of clocks by which to process data received from the field sensors 106 (FIG. 1). Specifically, the field sensors 106 may communicate data to the remote computing device 104 at predetermined intervals (such as 15 minutes or other timeframe). However, for a particular data analysis, the user may wish to process the data at a shorter or longer amount of time. Accordingly, the user may select one of the clock cycles in the clocks section 450. If the user wishes to process the received data at a longer interval, the remote computing device 104 may simply process a subset of the received data points. If the user wishes to process the received data at shorter intervals that was received, the remote computing device 104 may interpolate the data to provide the requested period.

Also included in FIG. 4B is a clock name, a period, and an offset, as well as an add option 451, which allows the user to define other clock cycles (and offsets) by which to process the data. This may allow the user to monitor module data and/or other data with a high precision.

FIG. 4C depicts a model section 452 of the user interface 230 from FIG. 2, according to embodiments disclosed herein. As illustrated, the model section 452 may include a junction area 454a and a pipe area 454b. The junction area 454a may allow the user to identify which junctions to include in the canvas section 238. Similarly, if the user wishes to include a pipe into the canvas section 238, the user may select one or more of the listed pipes. Other components of the utility may also be listed in the model section 452. Additionally, some embodiments are configured to provide an indication in the map section 232 to provide the user with an identification of the selected component.

FIG. 4D depicts a district metered (DMA) section 456 of the user interface 230 from FIG. 2, according to embodiments disclosed herein. As illustrated, the DMA section 456 includes a listing of DMAs that are currently associated with the utility. Specifically, a DMA may be a predetermined area and/or a subset of the entire utility to which both flow in and flow out may be measured. While many current utilities statically assign DMAs, such static assignment may have drawbacks. As an example, a DMA may become inaccurate if a field sensor 106 in the DMA malfunctions, if a break or leak in a pipe occurs and/or if other issue develops. Accordingly, in these current situations, the DMAs become extremely inaccurate.

Specifically, embodiments described herein are configured to receive real-time updates from the field sensors 106 and may thus identify when an issue develops. Accordingly DMAs, as dynamically determined by the remote computing device 104, may be continuously, periodically, and/or otherwise updated to accommodate for these changes in the utility. As an example, if a DMA is determined and a break is identified (by a user and/or by the remote computing device 104), the remote computing device 104 may recognize that the DMA may no longer be accurate and automatically determine an alteration that may be made to ensure accuracy of monitoring flow into and out of an area. By altering one DMA, other DMAs in the utility may also be altered by the remote computing device 104, depending on the embodiment.

In some embodiments, the remote computing device 104 may provide a user option for the user to create and/or edit a DMA. Such options may be useful in situations where a user has identified an issue with the utility that the remote computing device 104 may not yet recognize. Similar options for combining DMAs and/or breaking a DMA may also be provided.

Accordingly, embodiments of the DMA section 456 may include one or more DMAs. The user may select the one or more DMAs, which may change the map section 232 (FIG. 2) to highlight the selected DMA. Additional information, such as a graphical representation in the graphical section 236 (FIG. 2) and/or other data may also be provided. The DMA section 456 may additionally provide options to view and/or alter subsets of the utility, such as at least a portion of a DMA, depending on the embodiment.

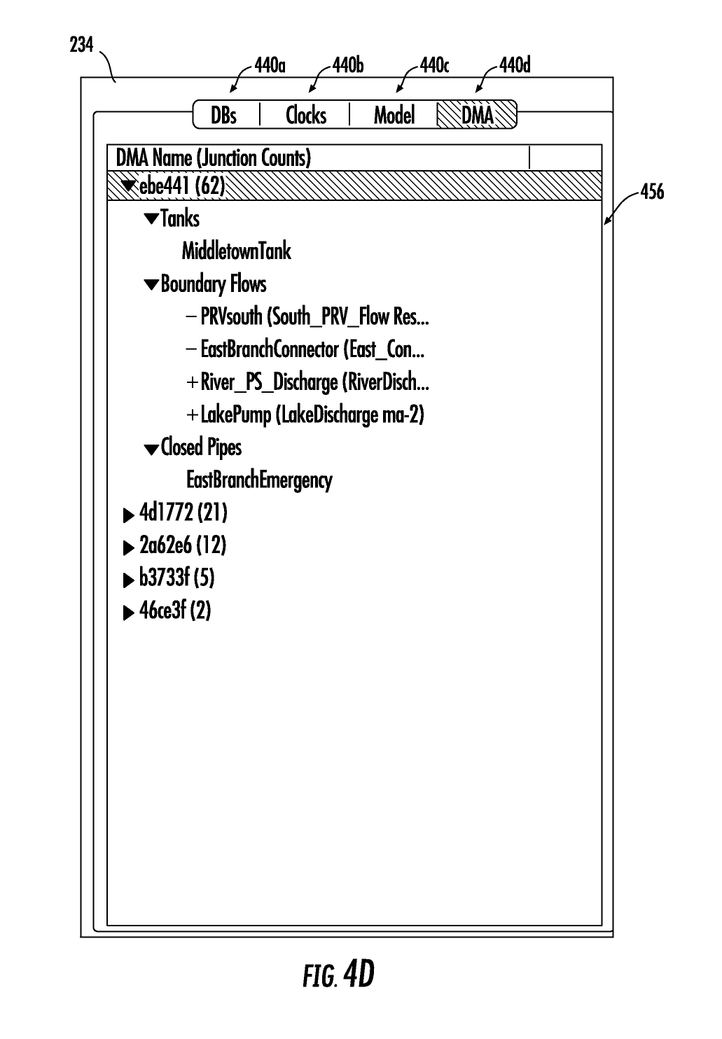

FIG. 5 depicts a graphical section 236 of the user interface 230 from FIG. 2, according to embodiments disclosed herein. As illustrated, the graphical section 236 may provide a graphical representation of data associated with the utility. As an example, flow rates for one or more pipes, flow rates of one or more DMAs, status of one or more tanks, status of one or more pumps, and/or other data may be depicted. As discussed above, the sample rate may be determined by the field sensors 106 and/or the remote computing device 104. If the user wishes to view the data at a quicker sample rate, the remote computing device 104 may interpolate between data points to populate the graphical section 236. Additionally, as illustrated, one or more data sets 540a-540e may be depicted. Options for adding a time series, moving a time series to a primary or secondary access, viewing aggregated sources and/or copying to canvas section 238 are also provided.

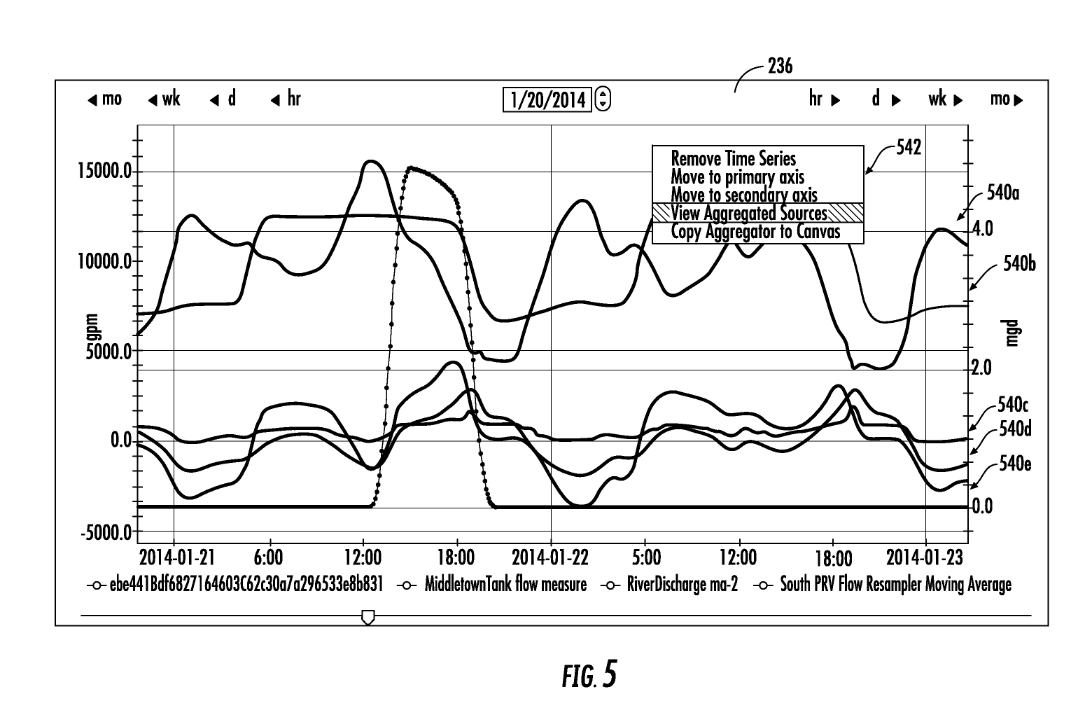

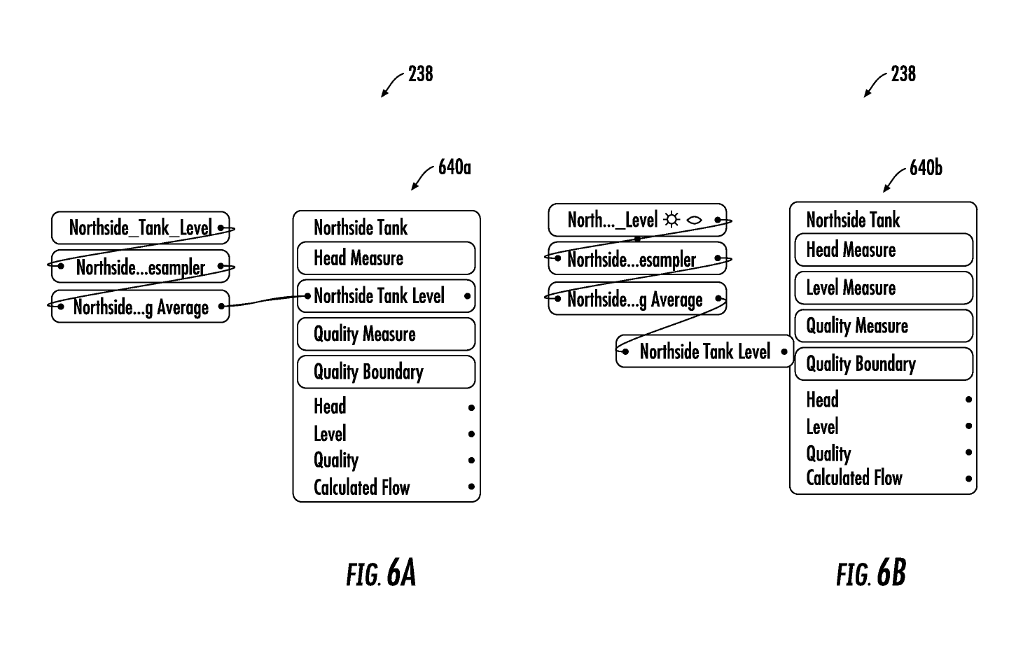

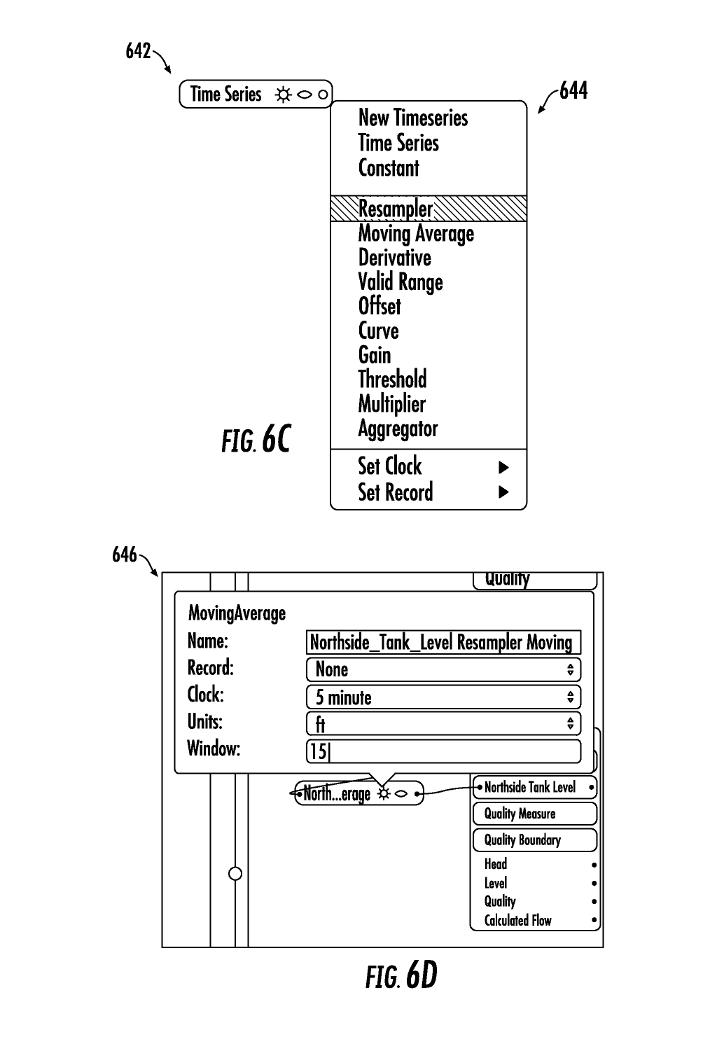

FIGS. 6A-6D depict a canvas section 238 of the user interface 230 from FIG. 2, according to embodiments disclosed herein. As illustrated in FIGS. 6A and 6B, the canvas section 238 may receive one or more components of the utility for constructing a programming module, such as modules 640a, 640b in FIGS. 6A and 6B. As an example, the module 640a in FIG. 6A may be created to provide head measure, Northside tank level, a quality measure, and a quality boundary. Accordingly, the user may further develop the module by adding components to the module through a “drag and drop” or other similar interface in the canvas section 238. As an example, the user may capture a component from the map section 232 and/or from the utility information section 234. Connections between the components of the modules 640a, 640b may be linked together to provide a measurement or calculation of data from the components. As illustrated, the Northside tank level, the Northside Resampler, and the Northside Moving Average are components that are utilized in the module. Similarly in the module 640b, the Northside level component, the Northside Resampler, the Northside Moving Average, and the Northside tank level are linked to the Northside tank module.

Accordingly, the modules 640a, 640b may be created by the user to monitor a portion of the utility, to create simulations, etc. As an example, if the user wishes to monitor the flow rate of a neighborhood, he/she may create a module that will provide the desired information. Similarly, if the user wishes to monitor fill rates and depletion rates of a tank, a separate module may be created. These modules may be edited and/or updated, depending on the particular embodiment.

Additionally, the user may create one or more modules to represent a hypothetical usage scenario that could occur to the utility. As an example, if the user wishes to determine the effect if a predetermined water line were to break, the user may simulate this hypothetical usage scenario. The remote computing device 104 may then determine the consequences for this hypothetical usage scenario. Additionally, some embodiments are configured to determine a solution to the hypothetical usage scenario, and provide that solution to the user. Depending on the particular module, the solution and/or other data may be provided via the graphical section 236, the map section 232, and/or via other mechanisms.

Similarly FIG. 6C illustrates options 644 that may be provided for a time series component 642 of a module that has been provided. Specifically, the options 644 that may be provided the time series component 642 include options for a new time series, a time series constant, a resampler, a moving average, a derivative, a valid range, an offset, a curve, a gain, a threshold, a multiplier, and an aggregator. Also included are options for setting a clock and setting a record. Thus, with regard to time series component 642, various mathematical manipulations may be performed on the data.

FIG. 6D illustrates options 646 that may be provided in response to selection of the moving average option from FIG. 6C. Specifically, a moving average may be calculated on the Northside tank level. A record may be set, as well as a clock, units, and a window. This mathematical manipulation of the data may provide the user with insights to various portions of the utility. Similarly, other mathematical manipulations may be provided with similar options.

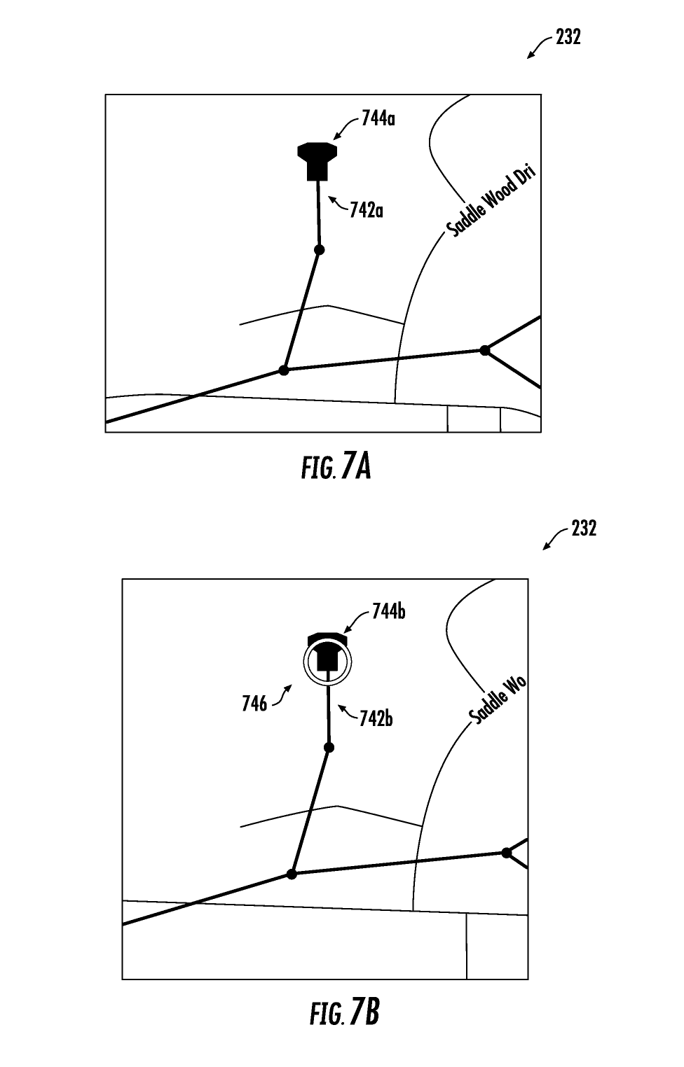

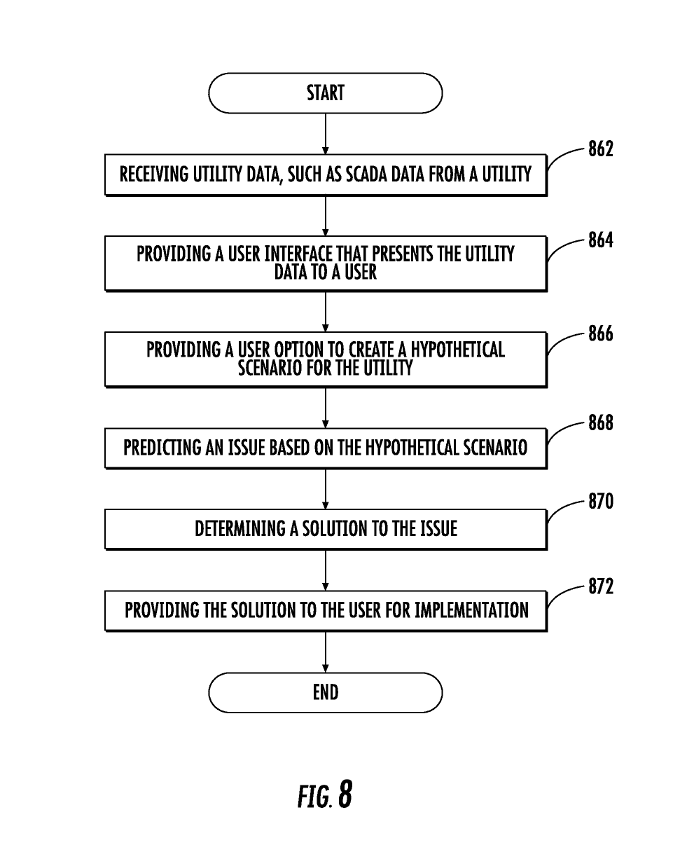

FIGS. 7A-7B depict a change in a utility system, as provided in the map section 232 of the user interface 230 of FIG. 2, according to embodiments disclosed herein. As illustrated in FIG. 7A, the map section 232 may provide a water line 742a, such as a pipe, as well as a tank 744a. Additionally, the user may use a “drag-and-drop” or similar mechanism to configure the remote computing device 104 to begin receiving data from the respective field sensors 106 that corresponds an instrumented property of the represented field component, shown here as the tank 744a. By selecting the tank 744a in the map section 232, additional information related to the tank may be provided, including information related to a real-time alert that indicates that there is an issue with the tank 744a. This information may provide a user option to contact repair personnel in the field for addressing the issue. Additionally, some embodiments of the remote computing device 104 may be configured to determine a desired response time that is required to prevent further issues. This may be a calculation of status over a predetermined time, an historical time that issues have occurred, etc. Regardless, the field personnel may be contacted, if deemed necessary, by either the remote computing device 104 or the user to address the issue.

While in some embodiments the remote computing device 104 may merely identify features of the system, some embodiments are configured to also determine a solution to an issue. As an example, if a water line breaks, the remote computing device 104 may provide instructions on which pumps to disable, and how to reroute water flow to address the issue. Instructions for personnel to repair the break may also be determined and provided by the remote computing device 104.

FIG. 7B illustrates a graphical annotation 746 indicating that a real time sensor is associated with the map representation depicted in the map section 232. In some embodiments, this alert may be provided automatically, upon a determination by the remote computing device 104 that an issue has been found, by a user section of the sensor, and/or via other mechanism. Some embodiments may also provide a user option to remove the alert from the map section 232.

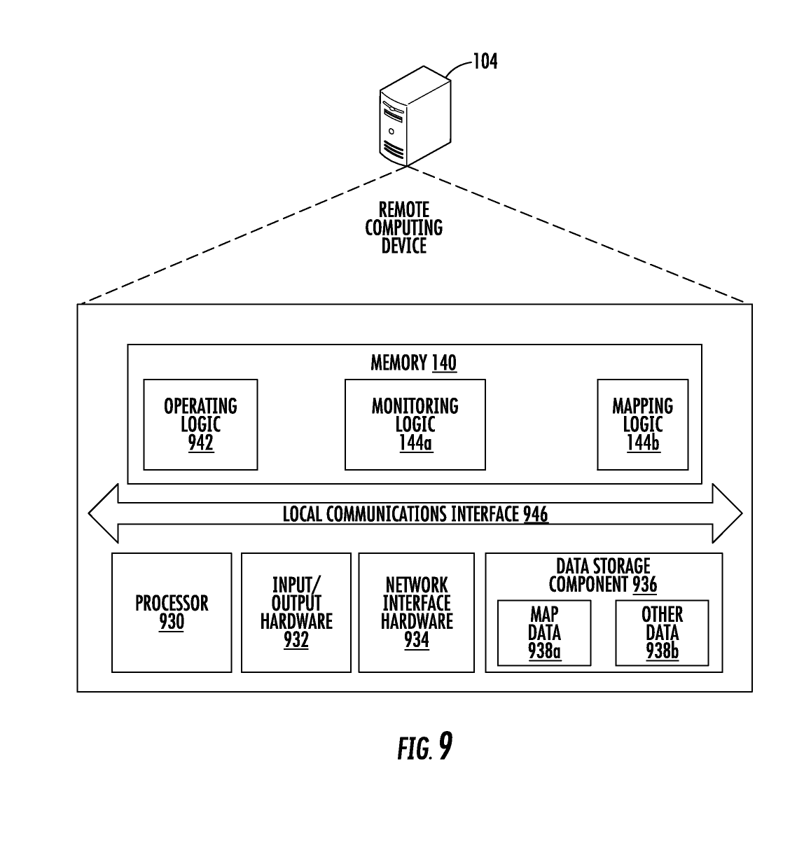

FIG. 8 depicts a flowchart for providing monitoring of one or more utilities, according to embodiments disclosed herein. As illustrated in block 862, utility data, such as SCADA data may be received from a utility or other entity. In block 864, a user interface that presents data related to the utility data to a user may be provided. In some embodiments, the data related to the utility data may be the actual utility data. However, in some embodiments, the data related to the utility data may include synthesized data based on a characteristic, such as a physical characteristic and/or mathematical characteristic of the utility. Accordingly, some embodiments may be configured to synthesize the utility data to create the synthesized data. Regardless, in block 866, a user option may be provided to create a hypothetical scenario for the utility. In block 868, an issue based on the hypothetical scenario may be predicted. In block 870, a solution to the issue may be determined. In block 872, the solution may be provided to the user for implementation.

FIG. 9 depicts a remote computing device 104 for utility monitoring, according to one or more embodiments disclosed herein. As illustrated, the remote computing device 104 may include a processor 930, input/output hardware 932, network interface hardware 934, a data storage component 936 (which stores map data 938a, and other data 938b), and the memory component 140. The memory component 140 may be configured as volatile and/or nonvolatile memory and as such, may include random access memory (including SRAM, DRAM, and/or other types of RAM), flash memory, secure digital (SD) memory, registers, compact discs (CD), digital versatile discs (DVD), and/or other types of non-transitory computer-readable mediums. Depending on the particular embodiment, these non-transitory computer-readable mediums may reside within the remote computing device 104 and/or external to the remote computing device 104.

The memory component 140 may store operating logic 942, the monitoring logic 144a and the mapping logic 144b. The monitoring logic 144a and the mapping logic 144b may each include a plurality of different pieces of logic, each of which may be embodied as a computer program, firmware, and/or hardware, as an example. A local interface 946 is also included in FIG. 9 and may be implemented as a bus or other communication interface to facilitate communication among the components of the remote computing device 104.

The processor 930 may include any processing component operable to receive and execute instructions (such as from a data storage component 936 and/or the memory component 140). As described above, the input/output hardware 932 may include and/or be configured to interface with the field sensors 106. Similarly, the network interface hardware 934 may include and/or be configured for communicating with any wired or wireless networking hardware, including an antenna, a modem, a LAN port, wireless fidelity (Wi-Fi) card, WiMax card, mobile communications hardware, and/or other hardware for communicating with other networks and/or devices (such as if connected to the field sensors 106). From this connection, communication may be facilitated between the remote computing device 104, the user computing device 102, the field sensors 106, and/or other components.

The operating logic 942 may include an operating system and/or other software for managing components of the remote computing device 104. Similarly, as discussed above, the monitoring logic 144a may reside in the memory component 134 and may be configured to cause the processor 930 to monitor data from the field sensors 106. Similarly, the mapping logic 144b may be utilized to analyze data from the field sensors 106 for creating the user interfaces and other data described above.

It should be understood that while the components in FIG. 9 are illustrated as residing within the remote computing device 104, this is merely an example. In some embodiments, one or more of the components may reside external to the remote computing device 104. It should also be understood that, while the remote computing device 104 is illustrated as a single device, this is also merely an example. In some embodiments, the monitoring logic 144a and the mapping logic 144b may reside on different computing devices. As an example, one or more of the functionalities and/or components described herein may be provided by the user computing device 102, field sensors 106, or other devices, which may be coupled to the remote computing device 104 via the network 100.

Additionally, while the remote computing device 104 is illustrated with the monitoring logic 144a and the mapping logic 144b as separate logical components, this is also an example. In some embodiments, a single piece of logic may cause the remote computing device 104 to provide the described functionality.

As described above, embodiments for utility monitoring may provide the ability to dynamically monitor a utility in real time. DMAs may be automatically altered in response to a determination that a system change has occurred. Additionally, a user interface for providing a canvas section to provide user-defined and customizable modules to predict and/or monitor one or more portions of a utility are also provided.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A method for utility monitoring, comprising:
receiving, by a computing device, utility data, wherein the utility data includes operational data of a utility;
providing, by the computing device, a user interface that presents data related to the utility data to a user;
providing, by the computing device, a user option to create a hypothetical usage scenario for the utility;
predicting, by the computing device, an issue based on the hypothetical usage scenario;
determining, by the computing device, a solution to the issue; and
providing, by the computing device, the solution to the user for implementation.

2. The method of claim 1, wherein the user interface provides at least one of the following:
a time series section of the operational data; and
a canvas section that provides options for monitoring user-defined sections of the utility.

3. The method of claim 1, further comprising utilizing the utility data to synthesize a characteristic of the data, wherein the characteristic includes at least one of the following: a physical characteristic of the utility and a mathematical characteristic of the utility.

4. The method of claim 3, wherein the data related to the utility data include at least one of the following: the utility data received by the computing device and the synthesized data.

5. The method of claim 1, further comprising:
dynamically determining a district metered area (DMA) based on the operational data; and
providing real-time monitoring of the DMA.

6. The method of claim 1, further comprising:
determining an different issue with the utility data;
determining a desired response time for addressing the different issue; and
providing an alert related to the different issue to the user.

7. The method of claim 1, further comprising providing a user interface that provides an option to select a database, wherein the database includes predetermined data, a representation of the utility, and a canvas section for representing the predetermined data as an icon and functionality to allow the user to graphically manipulate the icon on the canvas section to mathematically manipulate the predetermined data based on operation of the utility.

8. A system for utility monitoring comprising:
a processor; and
a memory component that stores logic that, when executed by the processor, causes the system to perform at least the following:
receive utility data from a utility, wherein the utility data includes operational data of the utility for a predetermined area of the utility;
determine a subset of the utility that identifies a district metered area (DMA);
determine a first flow rate into the subset of the utility;
determine a second flow rate out of the subset of the utility;
detect a change in the utility based on at least one of the following: the first flow rate and the second flow rate;
alter the subset of the utility, based on the change; and
provide data related to the subset to a user.

9. The system of claim 8, wherein the logic further causes the system to provide a user interface that presents the utility data to the user, wherein the user interface provides a time series section of the operational data.

10. The system of claim 8, wherein the logic further causes the system to provide a user interface that presents the utility data to the user, wherein the user interface provides canvas section that provides options for monitoring user-defined sections of the utility.

11. The system of claim 8, wherein the logic further causes the system to perform the following:
provide a user option to create a hypothetical usage scenario for the utility; and
predict an issue based on the hypothetical usage scenario.

12. The system of claim 8, wherein the logic further causes the system to provide real-time monitoring of the DMA.

13. The system of claim 8, wherein the logic further causes the system to perform at least the following:
determine an issue with the utility data;
determine a desired response time for addressing the issue; and
provide an alert related to the issue to the user.

14. The system of claim 8, wherein the utility is a water utility, wherein the logic further causes the system to perform at least the following:
determine flow data for a plurality of points within the DMA;
provide user interface depicting the DMA;
provide an option for the user to select at least one of the plurality of points; and
in response to receiving a user selection of one of the points, provide data related to the selected point.

15. A non-transitory computer-readable medium that stores logic that, when executed by a computing device, causes the computing device to perform at least the following:
receive utility data from a utility, wherein the utility data includes operational data of the utility for a predetermined area of the utility;
determine a subset of the utility that identifies a district metered area (DMA) based on the operational data;
detect a change in the utility;
automatically alter the subset, based on the change; and
provide data related to the subset to a user.

16. The non-transitory computer-readable medium of claim 15, wherein the logic further causes the computing device to provide a user interface, wherein the user interface includes a time series section of the operational data.

17. The non-transitory computer-readable medium of claim 15, wherein the logic further causes the computing device to provide a user interface, wherein the user interface provides a canvas section that provides options for monitoring user-defined sections of the utility.

18. The non-transitory computer-readable medium of claim 15, wherein the logic further causes the computing device to perform at least the following:
provide real-time monitoring of the DMA.

19. The non-transitory computer-readable medium of claim 15, wherein the logic further causes the computing device to perform at least the following:
determine an issue with the utility data;
determine a desired response time for addressing the issue; and
provide an alert related to the issue to the user.

20. The non-transitory computer-readable medium of claim 15, wherein the utility is a water utility, wherein the logic further causes the computing device to perform at least the following:
determine flow data for a plurality of points within at least one of the DMA;
provide an option for the user to select at least one of the plurality of points; and
in response to receiving a user selection of one of the points, provide data related to the selected point.
